(19) United States
(12) Patent Application Publication
(10) Pub. No.: US 2025/0236719 A1
(43) Pub. Date: Jul. 24, 2025

(54) RESIN COMPOSITION

(71) Applicant: Murata Manufacturing Co., Ltd., Kyoto-fu (JP)

(72) Inventor: Rikiya SANO, Nagaokakyo-shi (JP)

(73) Assignee: Murata Manufacturing Co., Ltd., Kyoto-fu (JP)

(21) Appl. No.: 19/033,209

(22) Filed: Jan. 21, 2025

(30) Foreign Application Priority Data
Jan. 22, 2024 (JP) 2024-007550

(51) Int. Cl. C08K 3/40; C08J 5/18; G03F 7/34

(52) U.S. Cl. CPC C08K 3/40; C08J 5/18; G03F 7/343; C08K 2201/005; C08K 2201/014

(57) ABSTRACT

A resin composition that reduces a decrease in glass viscosity and makes the glass less likely to be over-sintered, when the resin composition is subjected to sintering together with a conductive layer (in particular, a conductive layer containing Ag). A resin composition includes a glass frit, an inorganic filler, an alkali-soluble resin, a photosensitive monomer, and a photopolymerization initiator, where the rate of decrease in the complex viscosity of the glass frit with 7% by weight or less of Ag added to the glass frit is less than 40% at 900° C. and less than 60% at 926° C., as compared with a case without Ag added.

### CROSS-REFERENCE TO RELATED APPLICATION

This application claims benefit of priority to Japanese Patent Application No. 2024-007500, filed Jan. 22, 2024, the entire content of which is incorporated herein by reference.

### BACKGROUND

### Technical Field

The present disclosure relates to a resin composition.

### Background Art

For forming insulating layers for electronic components, an insulator paste including a glass powder may be used as in Japanese Patent Application Laid-Open No. H11-120823.

### SUMMARY

In the fabrication of an electronic component, an insulating layer formed from a resin composition including a glass powder may be subjected to lamination and sintering together with a conductive layer. The present inventor has found that the glass of the insulating layer adjacent to the conductive layer is likely to be over-sintered at the time of sintering, which may cause defects such as voids to be generated in the insulating layer in the vicinity of the interface between the insulating layer and the conductive layer.

Accordingly, the present disclosure is intended to provide a resin composition that makes it possible to prepare an insulating layer in which glass is less likely to be over-sintered when the insulating layer is subjected to sintering together with a conductive layer (in particular, a conductive layer containing Ag).

The present disclosure provides a resin composition including a glass frit, an inorganic filler, an alkali-soluble resin, a photosensitive monomer, and a photopolymerization initiator, where the rate of decrease in the complex viscosity of the glass frit with 7% by weight of Ag added to the glass frit is less than 40% at 900° C. and less than 60% at 926° C., as compared with a case without Ag added.

When an insulating layer is subjected to sintering together with a conductive layer (in particular, a conductive layer containing Ag), it is possible to prepare, from the resin composition according to the present disclosure, an insulating layer in which glass is unlikely to be over-sintered.

### BRIEF DESCRIPTION OF THE DRAWINGS

FIG. 1 shows a ternary composition diagram of glass according to an embodiment;

FIG. 2 shows a ternary composition diagram of glass according to an embodiment;

FIG. 3 shows a schematic sectional view of an Ag-GL co-sintered body;

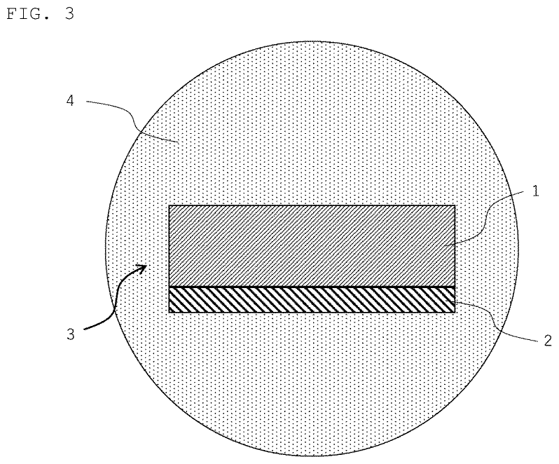

FIG. 4 is a representative view of a sectional image of an internal electrode;

FIG. 5 shows a binarized image of FIG. 4;

FIG. 6 shows an SEM image of a co-sintered body of glass that has a glass composition according to Example 1 and an electrode including silver; and

FIG. 7 shows an SEM image of a co-sintered body of glass that has a glass composition according to Comparative Example 2 and an electrode including silver.

### DETAILED DESCRIPTION

Hereinafter, the resin composition according to the present disclosure will be described in more detail. Although the description will be made with reference to the drawings as necessary, various elements in the drawings are only schematically and exemplarily illustrated for the understanding of the resin composition according to the present disclosure, and appearances and/or dimensional ratios may be different from actual ones.

Various numerical ranges mentioned herein are intended to include the numerical values themselves of the lower and upper limits. More specifically, when a numerical range such as 1 or more and 10 or less (i.e., from 1 to 10) is taken as an example, the example can be interpreted as including the lower limit of “1” and also including the upper limit of “10”.

### <Resin Composition>

A resin composition according to the present disclosure includes a glass frit, an inorganic filler, an alkali-soluble resin, a photosensitive monomer, and a photopolymerization initiator, and the rate of decrease in the complex viscosity of the glass frit with 7% by weight of Ag added to the glass frit is less than 40% at 900° C. and less than 60% at 926° C., as compared with a case without Ag added.

The glass frit with 7% by weight of Ag added to the glass frit means a glass frit obtained by adding 7% by weight of simple substance Ag, that is, metallic silver based on the weight of the glass frit.

When an insulating layer is subjected to sintering together with a conductive layer (in particular, a conductive layer containing Ag), it is possible to prepare, from the resin composition according to the present disclosure, an insulating layer in which glass is less likely to be over-sintered.

Conventionally, metal ions (for example, Ag ions) included in the conductive layer are diffused by sintering into the glass of an insulating layer adjacent to the conductive layer, thereby making the viscosity of the glass likely to be decreased. The glass with the viscosity reduced is more likely to be sintered, and as a result, there is concern that the glass in the insulating layer will be over-sintered. Such over-sintering may cause defects such as cracks and vacancies in the insulating layer. In particular, because of the glass of the insulating layer and the metal of the conductive layer in contact with each other at the interface between the insulating layer and the conductive layer, the viscosity of the glass of the insulating layer at the interface is more likely to be decreased at the time of sintering, and is more likely to be over-sintered than the other glass of the insulating layer than that at the interface.

The glass frit included in the resin composition according to the present disclosure has a feature in high-temperature rheology in the case of sintering together with a conductive layer. Specifically, the complex viscosity of the glass frit according to the present disclosure is less likely to be decreased if the glass frit is subjected to sintering together with a conductive layer. In particular, the complex viscosity of the glass frit included in the resin composition according to the present disclosure is less likely to be decreased if the glass frit is subjected to sintering together with an Ag-containing conductive layer. This is because metal ions, particularly Ag ions, from the conductive layer are less likely to be diffused into the glass frit softened by the sintering.

In addition, in an insulating layer prepared from the resin composition according to the present disclosure, metal ions, particularly Ag ions, are less likely to be diffused as described above, and thus, the insulation reliability of the insulating layer subjected to sintering is easily maintained. Accordingly, the performance and characteristics of an electronic component in which the resin composition according to the present disclosure is used, for example, an inductor are more easily maintained.

The glass frit, inorganic filler, alkali-soluble resin, photosensitive monomer, and photopolymerization initiator included in the resin composition according to the present disclosure will be described below.

### [Glass Frit]

The glass frit is powdered glass, which is also referred to as a glass powder. The glass frit can be softened to turn into a liquid phase when the resin composition is subjected to sintering.

### (Component)

The glass frit is an inorganic powder containing an oxide as a main component. Specifically, the glass frit includes an oxide of at least one element selected from the group consisting of Si, B, Ni, Cu, Pd, Al, Ti, Zr, Zn, Ga, Bi, Pb, Nb, Fe, Co, V, alkali metals, alkaline earth metals, and lanthanoids.

In an embodiment, the glass frit includes at least one selected from the group consisting of SiO₂, Al₂O₃, B₂O₃, K₂O, Li₂O, Na₂O, CaO, MgO, La₂O₃, ZnO, TiO₂, and ZrO₂.

In an embodiment, the glass frit according to the present disclosure includes SiO₂, X₂O₃(X is Al or B), and R₂O (R is an alkali metal element). As a preferred aspect, the glass frit according to the present disclosure includes SiO₂, Al₂O₃ or B₂O₃, and K₂O or Li₂O.

When the glass frit includes a smaller amount of X (that is, Al or B) and a larger amount of Si, the rate of decrease in the complex viscosity of glass with Ag added is more easily reduced. X can have a tetracoordinate structure together with Ag, and thus, Ag is more likely to be diffused into the glass of a glass frit including a larger amount of X (that is, the solubility of Ag in the glass is likely to be increased). It is difficult or not possible for Si to have a tetracoordinate structure together with Ag, Ag is less likely to be diffused into the glass of a glass frit including a larger amount of Si.

In an embodiment, the ratio of the amount of X₂O₃ to the total amount of SiO₂ and X₂O₃ included in the glass frit may be less than 0.200. From the viewpoint of making the glass frit less likely to be over-sintered, X₂O₃/(SiO₂+X₂O₃)<0.200 may be met, X₂O₃/(SiO₂+X₂O₃)<0.180, X₂O₃/(SiO₂+X₂O₃)<0.160, X₂O₃/(SiO₂+X₂O₃)<0.150, or X₂O₃/(SiO₂+X₂O₃)<0.145 may be met.

When the amount of R (that is, an alkali metal) is adjusted such that the glass frit includes R in an amount in a certain range, the rate of decrease in the complex viscosity of glass with Ag added is more easily reduced. Increasing the amount of R reduces the basicity of the glass, and makes Ag more likely to be diffused into the glass. Reducing the amount of R makes the complex viscosity of the glass at high temperature more likely to be decreased, and makes Ag more likely to be diffused into the glass.

In an embodiment, the ratio of the amount of R₂O to the total amount of SiO₂ and X₂O₃ included in the glass frit may be more than 0.008 and less than 0.042. From the viewpoint of making the glass frit less likely to be over-sintered, 0.008<R₂O/(SiO₂+X₂O₃)<0.042 may be met, 0.009<R₂O/(SiO₂+X₂O₃)<0.042, 0.010<R₂O/(SiO₂+X₂O₃)<0.037, 0.010<R₂O/(SiO₂+X₂O₃)<0.031, 0.014<R₂O/(SiO₂+X₂O₃)<0.031, or 0.020<R₂O/(SiO₂+X₂O₃)<0.031 may be met.

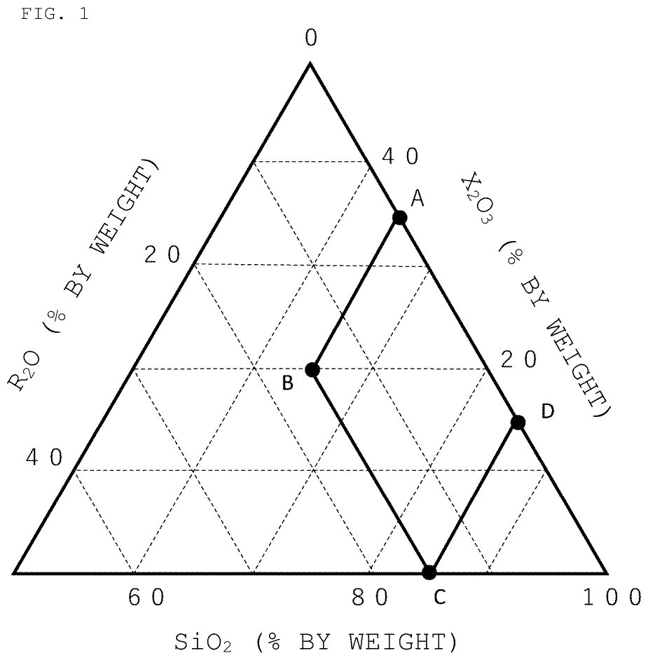

In an embodiment, the ratios by weight of SiO₂, X₂O₃, and R₂O are selected to fall within a region bounded by points A (65,35,0), B (65,20,15), C (85,0,15), and D (85,15,0) in the ternary composition diagram shown in FIG. 1.

Selecting the composition of the glass as described above allows the softening point of the glass to fall within the range of 700° C. or higher and 1050° C. or lower (i.e., from 700° C. to 1050° C.). Accordingly, the glass is low in reactivity with other materials such as an electrode material, a sintered body can be thus obtained at a sintering temperature of, for example, 900° C. or higher and 1050° C. or lower (i.e., from 900° C. to 1050° C.). Thus, the insulation property of an electrically insulating layer formed can be made excellent, and good workability can also be achieved. In addition, the relative permittivity of the glass can be made as low as less than 7.0, and the glass can be made suitable for applications to substrates with high-frequency circuits and electronic components.

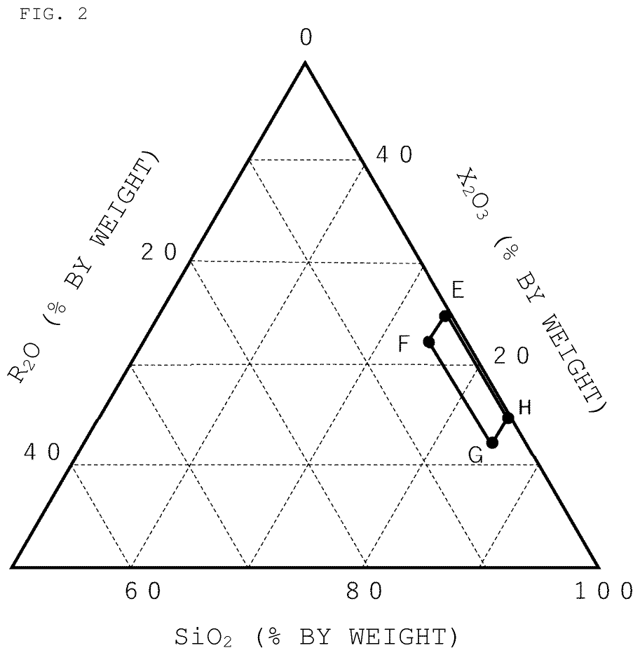

In an embodiment, the ratios by weight of SiO₂, X₂O₃, and R₂O are selected to fall within a region bounded by points E (75,24.5,0.5), F (75,22,3), G (85,12,3), and H (85,14.5,0.5) in the ternary composition diagram shown in FIG. 2. Selecting the composition of the glass as described above allows the softening point of the glass to fall within the range of 750° C. or higher and 940° C. or lower (i.e., from 750° C. to 940° C.), and thus, the glass can be made sintered by firing at a temperature of 950° C. or lower for forming an electrically insulating layer. Accordingly, the workability is further improved, and the reactivity with other materials such as an electrode material can be further reduced.

In the ternary composition diagram shown in FIG. 1, X₂O₃ and R₂O may be B₂O₃ and K₂O from the viewpoint of further improving the workability and further reducing the reactivity with other materials such as an electrode material.

In an embodiment, the glass frit according to the present disclosure may be a borosilicate glass. The borosilicate glass in the present disclosure is glass essentially containing Si and B, which may optionally contain the elements listed above. Examples of the component of the borosilicate glass include, but are not limited to, the following combinations.

SiO₂+B₂O₃+K₂O

SiO₂+B₂O₃+Li₂O

SiO₂+B₂O₃+Na₂O+K₂O+CaO+Al₂O₃

SiO₂+B₂O₃+Na₂O+K₂O+Al₂O₃

SiO₂+B₂O₃+Al₂O₃+CaO

SiO₂+B₂O₃+BaO+ZnO+Al₂O₃+MgO+La₂O₃

SiO₂+B₂O₃+CaO+Al₂O₃+Na₂O+K₂O

In an embodiment, the glass frit includes SiO₂, B₂O₃, and K₂O. According to such an embodiment, the rate of decrease in the complex viscosity of the glass frit with 7% by weight of Ag added to the glass frit can be further reduced.

The glass frit according to the present disclosure may include, besides the components listed above, components that can constitute glass, for adjusting various types of performance such as acid resistance, water resistance, durability, and heat resistance. For example, the glass frit according to the present disclosure may include one or more selected from the group consisting of Li₂O, CaO, ZnO, MgO, TiO₂, La₂O₃, and ZrO₂.

### (Particle Size)

The average particle size of the glass frit may be 0.1 μm or more, 0.4 μm or more, 0.7 μm or more, 1.0 μm or more, or 1.3 μm or more.

The average particle size of the glass frit may be 5.0 μm or less, 4.5 μm or less, 4.0 μm or less, 3.5 μm or less, or 3.0 μm or less.

When the particle size of the glass frit falls within the range mentioned above, the glass frit in the resin composition is more likely to be dispersed uniformly, and the smoothness of the surface of an insulating layer formed from the resin composition is more likely to be improved.

The average particle size of the glass frit is a particle diameter D50 at which the integrated particle volume from the small particle diameter side reaches 50% of the total particle volume in a particle size distribution determined by a laser diffraction/scattering method.

### (Complex Viscosity at 900° C.)

glass frit alone

The complex viscosity of the glass frit alone according to the present disclosure at 900° C. may be 1.0×10⁹ mPa·S or more, and from the viewpoint of making the glass frit less likely to be over-sintered, the complex viscosity may be 1.3×10⁹ mPa·S or more, 1.6×10⁹ mPa·S or more, 2.0×10⁹ mPa·S or more, 2.3×10⁹ mPa·S or more, or 3.0×10⁹ mPa·S or more.

The complex viscosity of the glass frit alone according to the present disclosure at 900° C. may be 15.0×10⁹ mPa·S or less, and from the viewpoint of making the glass frit less likely to be over-sintered, the complex viscosity may be 13.0×10⁹ mPa·S or less, 11.0×10⁹ mPa·S or less, 9.0×10⁹ mPa·S or less, or 7.0×10⁹ mPa·S or less.

### 7% by Weigh of Ag Added

The complex viscosity of the glass frit according to the present disclosure with 7% by weight of Ag added to the glass frit at 900° C. may be 1.0×10⁹ mPa·S or more, and from the viewpoint of making the glass frit less likely to be over-sintered, the complex viscosity may be 1.2×10⁹ mPa·S or more, 1.6×10⁹ mPa·S or more, or 2.5×10⁹ mPa·S or more.

The complex viscosity of the glass frit according to the present disclosure with 7% by weight of Ag added to the glass frit at 900° C. may be 15.0×10⁹ mPa·S or less, and from the viewpoint of making the glass frit less likely to be over-sintered, the complex viscosity may be 13.0×10⁹ mPa·S or less, 11.0×10⁹ mPa·S or less, 9.0×10⁹ mPa·S or less, or 7.0×10⁹ mPa·S or less.

### (Complex Viscosity at 926° C.)

glass frit alone

The complex viscosity of the glass frit alone according to the present disclosure at 926° C. may be 0.76×10⁹ mPa·S or more, and from the viewpoint of making the glass frit less likely to be over-sintered, the complex viscosity may be 1.0×10⁹ mPa·S or more, 1.3×10⁹ mPa·S or more, 1.6×10⁹ mPa·S or more, 2.0×10⁹ mPa·S or more, or 3.0×10⁹ mPa·S or more.

The complex viscosity of the glass frit alone according to the present disclosure at 926° C. may be 15.0×10⁹ mPa·S or less, and from the viewpoint of making the glass frit less likely to be over-sintered, the complex viscosity may be 13.0×10⁹ mPa·S or less, 11.0×10⁹ mPa·S or less, 9.0×10⁹ mPa·S or less, or 7.0×10⁹ mPa·S or less.

### 7% by Weigh of Ag Added

The complex viscosity of the glass frit according to the present disclosure with 7% by weight of Ag added to the glass frit at 926° C. may be 0.76×10⁹ mPa·S or more, and from the viewpoint of making the glass frit less likely to be over-sintered, the complex viscosity may be 1.0×10⁹ mPa·S or more, 1.3×10⁹ mPa·S or more, 1.6×10⁹ mPa·S or more, 2.0×10⁹ mPa·S or more, or 3.0×10⁹ mPa·S or more.

The complex viscosity of the glass frit according to the present disclosure with 7% by weight of Ag added to the glass frit at 926° C. may be 15.0×10⁹ mPa·S or less, and from the viewpoint of making the glass frit less likely to be over-sintered, the complex viscosity may be 13.0×10⁹ mPa·S or less, 11.0×10⁹ mPa·S or less, or 9.0×10⁹ mPa·S or less.

(Rate of Decrease in Complex Viscosity with Ag Added)

While the complex viscosity of the glass frit with Ag added thereto at a high temperature (in other words, Ag-added complex viscosity) is decreased as compared with the complex viscosity of the glass frit without Ag added thereto at a high temperature, the degree of the decrease is low in the glass frit according to the present disclosure. Specifically, the rate of decrease in the complex viscosity of the glass frit according to the present disclosure with 7% by weight of Ag added to the glass frit is lower than that without any Ag added thereto.

It is to be noted that the glass frit without any Ag added thereto is not limited to a case in which the glass frit contains no Ag at all, that is, a case of 0% by weight, and also encompasses a case in which the glass frit contains substantially no Ag. The glass frit substantially no Ag may contain 0.01% by weight or less, 0.001% by weight, or 0.0001% by weight or less of Ag with respect to the glass frit.

rate of decrease at 900° C.

The rate of decrease in the complex viscosity of the glass frit according to the present disclosure with 7% by weight of Ag added to the glass frit may be, as compared with the case without Ag added, less than 40% at 900° C., and may be less than 35%, less than 30%, or less than 25% from the viewpoint of making the glass frit less likely to be over-sintered.

rate of decrease at 926° C.

The rate of decrease in the complex viscosity of the glass frit according to the present disclosure with 7% by weight of Ag added to the glass frit may be, as compared with the case without Ag added, less than 60% at 926° C., and may be less than 50%, less than 40%, less than 30%, or less than 25% from the viewpoint of making the glass frit less likely to be over-sintered.

The rates of decreases in the complex viscosity of the glass frit with Ag added thereto at 900° C. and 926° C. can be determined by the following formula.

“rate of decrease in complex viscosity of glass frit with Ag added=100−complex viscosity of glass frit with Ag added/complex viscosity of glass frit alone×100”

The above-described complex viscosities at 900° C. and 926° C. are not necessarily limited to the complex viscosities exactly at 900° C. and 926° C., and also encompasses complex viscosities at temperatures, which can be determined substantially to be complex viscosities at 900° C. and 926° C. For example, such temperatures may range from 900° C.±1° C. and 926° C.±1° C., and may range from 900° C.±2° C. and 926° C.±2° C.

### (Method for Measuring Complex Viscosity)

The complex viscosity of the glass frit according to the present disclosure can be measured with a high-temperature rheometer. The complex viscosity of the glass frit can be obtained by applying a pressure to the glass frit with a pressing machine or the like to prepare a green compact and measuring the green compact with a high-temperature rheometer. Specifically, the complex viscosity can be measured under the conditions listed in Tables 1 and 2 below.

TABLE 1
Conditions for Preparation of Green Compact

| Apparatus/Part | Pressing Machine | 20 t pressing machine |
|---|---|---|
| Material | Mold | φ = 1 cm circle |
| Processing | Load [t] | 10 |
| Conditions | Filling Depth [mm] | 5 |
| | Load Holding Time [sec] | 5 |

TABLE 2
Conditions for Measurement with High Temperature Rheometer

| | High | |
|---|---|---|
| Apparatus/Part | Temperature | MCR302 (manufactured |
| Material | Rheometer | by Anton Paar) |
| Measurement | Measurement | 550 to 950° C. |
| Conditions | Temperature | (step temperature rise |
| | | at 25° C./6 min) |
| | Measurement | any value of 0.1 to 10 Hz |
| | Frequency | |
| | Normal Force | 10N |

The glass frit with 7% by weight of Ag added thereto can be prepared in the following manner.

SiO₂, B₂O₃, and K₂CO₃ were respectively provided as starting materials, and mixed so as to have a glass composition with desired composition ratios by weight, and then each mixture obtained was melted at a temperature of 1700° C. to prepare a molten glass. Then, each molten glass was rapidly cooled with a cooling roll and then pulverized to prepare a glass powder.

The powder of the glass frit with an Ag powder weighed in a predetermined proportion and then mixed into the powder of the glass frit while stirring with a spatula for about 1 minute is formed into a green compact by a method for forming a green compact according to the disclosure of the present application.

The Ag powder may have a particle size, for example, with D50=2.0 μm or more and 5.0 μm or less (i.e., from 2.0 μm to 5.0 μm). The Ag powder can be obtained by a known method, and may be, for example, an atomized Ag powder. Ag powders with particle sizes other than the particle size mentioned above may be used, and for example, an Ag powder obtained by a wet reduction method may be used.

### (Softening Point)

The softening point of the glass frit of the present disclosure may be equal to or lower than the melting point of Ag. Such Ag means a simple substance of metal Ag, and the melting point of the Ag means 961° C. The softening point of the glass frit according to the present disclosure may be 950° C. or lower, 930° C. or lower, 900° C. or lower, 860° C. or lower, or 820° C. or lower. The softening point of the glass frit according to the present disclosure may be 650° C. or higher, 700° C. or higher, 730° C. or higher, 760° C. or higher, or 780° C. or higher.

The softening point of the glass frit can be obtained from thermogravimetric differential thermal analysis (TG-DTA). In the thermogravimetric differential thermal analysis, 30 mg of the glass frit with a median diameter (D50) of 0.1 μm or more and 5.0 μm or less (i.e., from 0.1 μm to 5.0 μm) was used, and a platinum pan was used as a container for the glass frit. The skirt (fourth inflection point) of the second endothermic peak as viewed from the low-temperature side of a DTA chart obtained by temperature increase from room temperature to 950° C. at 10° C./min under the air atmosphere with the use of α-alumina as a reference is defined as a glass softening point.

### (Content)

The content of the glass frit may be 10% by weight or more, 15% by weight or more, 20% by weight or more, 25% by weight or more, 30% by weight or more, or 35% by weight or more, with respect to the resin composition. The content of the glass frit may be 70% by weight or less, 60% by weight or less, 55% by weight or less, 50% by weight or less, 45% by weight or less, 40% by weight or less, or 35% by weight or less, with respect to the resin composition. In an aspect, from the viewpoint of making the glass frit less likely to be over-sintered, the content of the glass frit included may be 20% by weight or more and 50% by weight or less, preferably 30% by weight or more and 50% by weight or less, with respect to the resin composition.

### [Inorganic Filler]

The inorganic filler refers to a filler that is not melted when the resin composition is subjected to sintering. The inorganic filler is an inorganic filler other than the glass frit. The type of the inorganic filler is not particularly limited, and known inorganic fillers may be used. For example, metal oxides, silicate compounds, nitrides, carbides, minerals, and the like can be used for the inorganic filler.

In an embodiment, the resin composition may include at least one or more inorganic fillers from Mg₂SiO₄ (forsterite), CaSiO₃ (wollastonite), ZrO₂ (zirconia), Al₂O₃ (alumina), CeO (ceria), TiO₂ (titania), Fe₂O₃ (ferrite), SiO₂ (quartz), CoAl₂O₄ (cobalt aluminate), and perovskite-type oxides represented by ABO₃ as a general formula. From the viewpoint of crack suppression, the inorganic filler may be Al₂O₃ (alumina) and/or SiO₂ (quartz). The name in the parentheses means a compound or a mineral composed of the inorganic filler or containing the inorganic filler as a main component.

The perovskite-type oxides represented by ABO₃ as a general formula may be used, where the constituent element at the A site in the formula includes at least one selected from the group consisting of Ag, K, La, Sr, Ca, and Ba, and the constituent element at the B site in the formula includes at least one selected from the group consisting of Nb, Ca, Co, Ti, Zr, and Fe.

The combination of the inorganic fillers may be selected appropriately, depending on the use of the resin composition according to the present disclosure. For example, the resin composition may include therein an appropriate combination of inorganic fillers in view of the type, structure, and performance of an electronic component. Examples of the combination of the inorganic fillers include:

Mg₂SiO₄+Al₂O₃+SiO₂+ZrO₂

CaSiO₃+Al₂O₃+SiO₂+ZrO₂

Mg₂SiO₄+Al₂O₃++SiO₂

ABO₃+Fe₂O₃

Al₂O₃+SiO₂

Al₂O₃+SiO₂+CeO

Al₂O₃+SiO₂+CoAl₂O₄+TiO₂

### (Content)

The content of the inorganic filler may be 1% by weight or more, 3% by weight or more, 5% by weight or more, 10% by weight or more, 15% by weight or more, or 20% by weight or more, with respect to the resin composition. The content of the inorganic filer may be 40% by weight or less, 35% by weight or less, 30% by weight or less, 25% by weight or less, or 20% by weight or less, with respect to the resin composition. In an aspect, from the viewpoint of making the glass frit less likely to be over-sintered, the content of the inorganic filler included may be 1% by weight or more and 35% by weight or less, preferably 15% by weight or more and 25% by weight or less, with respect to the resin composition.

### [Alkali-Soluble Resin]

As the alkali-soluble resin, for example, resins such as an acrylic copolymer having a functional group such as a carboxy group in a side chain can be used, and specific examples thereof include a copolymer of an unsaturated carboxylic acid and an ethylenically unsaturated compound other than the unsaturated carboxylic acid. The resin composition according to the present disclosure may include one or more types of alkali-soluble resins.

Examples of the ethylenically unsaturated compound as the unsaturated carboxylic acid include acrylic acid, methacrylic acid, maleic acid, fumaric acid, vinylacetic acid, and acid anhydrides thereof. In addition, examples of the ethylenically unsaturated compound other than the unsaturated carboxylic acid include unsaturated carboxylic acid esters, and specific examples thereof include acrylic acid esters such as methyl acrylate and ethyl acrylate, methacrylic acid esters such as methyl methacrylate and ethyl methacrylate, and fumaric acid esters such as monoethyl fumarate.

Further, as the acrylic copolymer having a carboxy group in the side chain, an acrylic copolymer with an introduced unsaturated bond in the following form may be used.
(1) An acrylic monomer having a functional group, such as an epoxy group, capable of reacting with the carboxyl group in the side chain of the acrylic copolymer is added to the carboxyl group.
(2) After an unsaturated monocarboxylic acid is allowed to react with the acrylic copolymer with an epoxy group introduced instead of the carboxy group in the side chain, a saturated or unsaturated polycarboxylic anhydride is further introduced into the acrylic copolymer.

Furthermore, the acrylic copolymer having a carboxy group in the side chain preferably has a weight average molecular weight (Mw) of 50,000 or less and has an acid value of 30 mgKOH/g or more and 150 mgKOH/g or less.

### (Content)

The content of the alkali-soluble resin may be 5% by weight or more, 10% by weight or more, 15% by weight or more, 20% by weight or more, or 25% by weight or more, with respect to the resin composition. The content of the alkali-soluble resin may be 50% by weight or less, 45% by weight or less, 40% by weight or less, 35% by weight or less, 30% by weight or less, or 25% by weight or less, with respect to the resin composition. In an aspect, from the viewpoint of making the glass frit less likely to be over-sintered, the content of the alkali-soluble resin included may be 15% by weight or more and 45% by weight or less, preferably 25% by weight or more and 35% by weight or less, with respect to the resin composition.

### [Photosensitive Monomer]

For the photosensitive monomer, a compound having an ethylenically unsaturated double bond can be used. For the photosensitive monomer, a monofunctional or polyfunctional compound having a vinyl group, an allyl group, an acrylate group, a methacrylate group, or an acrylamide group may be used. The resin composition according to the present disclosure may include one or more types of photosensitive monomers.

For the photosensitive monomer may be, hexanediol triacrylate, tripropylene glycol triacrylate, trimethylolpropane triacrylate, EO-modified trimethylolpropane triacrylate, stearyl acrylate, tetrahydrofurfuryl acrylate, lauryl acrylate, 2-phenoxyethyl acrylate, isodecyl acrylate, isooctyl acrylate, tridecyl acrylate, caprolactone acrylate, ethoxylated nonylphenol acrylate, 1,3-butanediol diacrylate, 1,4-butanediol diacrylate, diethylene glycol diacrylate, tetraethylene glycol diacrylate, triethylene glycol diacrylate, ethoxylated bisphenol A diacrylate, propoxylated neopentyl glycol diacrylate, tris(2-hydroxyethyl)isocyanurate triacrylate, pentaerythritol triacrylate, propoxylated trimethylolpropane triacrylate, propoxylated glyceryl triacrylate, pentaerythritol tetraacrylate, ditrimethylolpropane tetraacrylate, ethoxylated pentaerythritol tetraacrylate, and the like can be used in addition to dipentaerythritol monohydroxypentaacrylate. In addition, the above-mentioned compound in which the some or all of the acrylate in the molecule of the compound is changed to a methacrylate can be used.

### (Content)

The content of the photosensitive monomer may be 1% by weight or more, 3% by weight or more, 5% by weight or more, or 10% by weight or more, with respect to the resin composition. The content of the photosensitive monomer may be 30% by weight or less, 25% by weight or less, 20% by weight or less, 15% by weight or less, 10% by weight or less, or 5% by weight or less, with respect to the resin composition. In an aspect, from the viewpoint of making the glass frit less likely to be over-sintered, the content of the photosensitive monomer included may be 1% by weight or more and 25% by weight or less, preferably 10% by weight or more and 15% by weight or less, with respect to the resin composition.

### [Photopolymerization Initiator]

The photopolymerization initiator is a component that is decomposed by irradiation with light energy such as ultraviolet rays to generate active species such as radicals and/or cations and start a polymerization reaction of a monomer. The photopolymerization initiator is not particularly limited, and from among conventionally known photopolymerization initiators, one type of photopolymerization initiator can be used alone, or two or more types of photopolymerization initiators can be used in appropriate combination, depending on the type of monomer and the like.

As the photopolymerization initiator, 2-methyl-1[4-(methylthio)phenyl]-2-morpholinopropane is used, and in addition, it is possible to use benzyl, benzoin ethyl ether, benzoin isobutyl ether, benzoin isopropyl ether, benzophenone, benzoylbenzoic acid, methyl benzoylbenzoate, 4-benzoyl-4′-methyldiphenyl sulfide, benzyl dimethyl ketal, 2-n-butoxy-4-dimethylaminobenzoate, 2-chlorothioxanthone, 2,4-diethylthioxanthone, 2,4-diisopropylthioxanthone, isopropylthioxanthone, 2-dimethylaminoethyl benzoate, ethyl p-dimethylaminobenzoate, isoamyl p-dimethylaminobenzoate, 3,3′-dimethyl-4-methoxybenzophenone, 2,4-dimethylthioxanthone, 1-(4-dodecylphenyl)-2-hydroxy-2-methylpropane-1-one, 2,2-dimethoxy-1,2-diphenylethane-1-one, hydroxycyclohexyl phenyl ketone, 2-hydroxy-2-methyl-1-phenylpropane-1-one, 1-[4-(2-hydroxyethoxy)-phenyl]-2-hydroxy-2-methyl-1-propane-1-one, methyl benzoylformate, 1-phenyl-1,2-propanedione-2-(o-ethoxycarbonyl)oxime, 2-benzyl-2-dimethylamino-1 (4-morpholinophenyl)-1-butanone, bis(2,6-dimethoxybenzoyl)-2,4,4-trimethylpentylphosphine oxide, bis(2,4,6-trimethylbenzoyl)phenylphosphine oxide, and the like.

### (Content)

The content of the photopolymerization initiator may be 0.1% by weight or more, 0.5% by weight or more, 1% by weight or more, 3% by weight or more, 5% by weight or more, or 10% by weight or more, with respect to the resin composition. The content of the photopolymerization initiator may be 20% by weight or less, 15% by weight or less, 10% by weight or less, 5% by weight or less, or 3% by weight or less, with respect to the resin composition. In an aspect, from the viewpoint of making the glass frit less likely to be over-sintered, the content of the photopolymerization initiator included may be 0.1% by weight or more and 10% by weight or less, preferably 1% by weight or more and 3% by weight or less, with respect to the resin composition.

### <Resin Composition Paste>

The resin composition paste according to the present disclosure includes the resin composition according to the present disclosure, a solvent, and a dispersant and/or a plasticizer. The resin composition paste according to the present disclosure may include both a dispersant and a plasticizer. The resin composition paste according to the present disclosure may include one of a dispersant and a plasticizer.

The resin composition included in the resin composition paste according to the present disclosure is as mentioned above.

### [Solvent]

The resin composition paste according to the present disclosure may include a solvent. The solvent is not particularly limited, and known solvents may be used. The solvent may be an organic solvent, and may be, for example, butyl carbitol acetate, butyl carbitol, ethyl carbitol acetate, ethyl carbitol, hexane, toluene, ethyl cellosolve, cyclohexanone, butyl cellosolve, butyl cellosolve acetate, diethylene glycol diethyl ether, diacetone alcohol, terpineol, methyl ethyl ketone, benzyl alcohol, methyl ethyl ketone, methyl isobutyl ketone, tetradecane, tetralin, propyl alcohol, isopropyl alcohol, dihydroterpineol, dihydroterpineol acetate, ethyl carbitol, 2,2,4-trimethyl-1,3-pentanediol monoisobutyrate (texanol), 1-(2-methoxy-2-methylethoxy)-2-propanol, dipropylene glycol monomethyl ether, or a combination thereof.

### (Content)

The content of the solvent may be selected appropriately in view of the degree of dispersion of the resin composition in the resin composition paste and the viscosity of the resin composition paste. For example, the content of the solvent may be 50% by weight or more, 60% by weight or more, 70% by weight or more, or 80% by weight or more, with respect to the resin composition paste. The content of the solvent may be 90% by weight or less, 80% by weight or less, 70% by weight or less, or 60% by weight or less, with respect to the resin composition.

### [Dispersant]

The resin composition paste according to the present disclosure may include a dispersant. The dispersant is included in the resin composition paste for dispersing at least the glass frit. The dispersant is not particularly limited as long as the dispersant is capable of dispersing at least the glass frit in the resin composition paste, and one type of dispersant may be used, or two or more types of dispersants may be used in mixture.

For the dispersant, nonionic dispersants, anionic dispersants, cationic dispersants, and the like can be used.

Ethyl celluloses, nitrocelluloses, polyvinyl acetates, polyoxyethylene alkyl ethers, polyoxyethylene polyoxypropylene alkyl ethers, polyoxyethylene polyoxybutylene alkyl ethers, polyoxyethylene polyoxypropylene glycols, polyethyleneimine ethoxylates, and the like may be used as the nonionic dispersants.

Alkyl ether sulfates, alkyl sulfates, alkenyl ether sulfates, alkenyl sulfates, olefin sulfonates, alkane sulfonates, saturated or unsaturated fatty acid salts, alkyl or alkenyl ether carboxylates, α-sulfonic fatty acid salts, N-acyl amino acid-type dispersants, phosphoric acid mono- or di-ester-type dispersants, sulfosuccinic acid esters, and the like may be used as the anionic dispersants.

Amine salt-type dispersants such as alkylamine salts, amino alcohol fatty acid derivatives, polyamine fatty acid derivatives, and imidazoline; alkyltrimethylammonium salts, dialkyl dimethyl ammonium salts, alkyldimethylbenzylammonium salts, pyridinium salts, alkylisoquinolinium salts, and the like may be used as the cationic dispersants.

### (Content)

The content of the dispersant may be 0.01% by weight or more, 0.05% by weight or more, 0.1% by weight or more, or 0.3% by weight or more, with respect to the resin composition paste. The content of the dispersant may be 15% by weight or less, 10% by weight or less, 5% by weight or less, or 1% by weight or less, or 0.5% by weight or less, with respect to the resin composition paste. In an aspect, from the viewpoint of making the glass frit less likely to be over-sintered, the content of the glass frit included may be 0.1% by weight or more and 10% by weight or less (i.e., from 0.1% by weight to 10% by weight), preferably 0.1% by weight or more and 0.5% by weight or less (i.e., from 0.1% by weight to 0.5% by weight), with respect to the resin composition.

When the dispersant is an anionic dispersant, the content of the anionic dispersant may fall within a range such that the total acid amount is 10% or more and 150% or less (i.e., from 10% to 150%) of the total base amount of the glass frit. This is because no sufficient dispersion effect is achieved when the content of the anionic dispersant is less than 10% of the total base amount of the glass powder, or because no significant improvement in dispersion effect is recognized if the anionic dispersant is added in excess of 150%. The total acid amount of the anionic dispersant and the total base amount of the glass frit can be quantified by a method such as a titration method.

### [Plasticizer]

The resin composition paste according to the present disclosure may include a plasticizer. The plasticizer is included to adjust the rheological property of the resin composition paste. The type of the plasticizer is not particularly limited, and known plasticizers can be used. For the plasticizer, one type of plasticizer may be used alone, or two or more types of plasticizers may be used in mixture.

For the plasticizer, a glycol derivative, a phthalic acid derivative, an isophthalic acid derivative, a tetrahydrophthalic acid derivative, an adipic acid derivative, a maleic acid derivative, a fumaric acid derivative, a trimellitic derivative, a pyromellitic derivative, a stearic acid derivative, an oleic acid derivative, an itaconic acid derivative, a ricinoleic derivative, or the like may be used.

### (Aspect Including Organic Vehicle)

In an embodiment, the resin composition paste according to the present disclosure includes the resin composition according to the present disclosure, an organic vehicle, and a dispersant and/or a plasticizer.

### [Organic Vehicle]

The organic vehicle includes a solvent and an organic binder.

As the solvent included in the organic vehicle, the solvents exemplified above can be used.

As the organic binder included in the organic vehicle, cellulose acetates, cellulose acetate butyrates, and the like can be exemplified as the cellulose ester-based compounds, ethyl celluloses, methyl celluloses, hydroxypropyl celluloses, hydroxyethyl celluloses, hydroxypropyl methyl celluloses, hydroxyethyl methyl celluloses, and the like can be exemplified as the cellulose ether compounds, polyacrylamides, polymethacrylates, polymethyl methacrylates, polyethyl methacrylate, and the like can be exemplified as the acrylic compounds, and polyvinyl butyrals, polyvinyl acetates, polyvinyl alcohols, and the like can be exemplified as the vinyl-based compounds. At least one of the organic binders can be selected and then used.

The content of the organic binder in the organic vehicle may be 5% by weight or more, 10%% by weight or more, or 15% by weight or more, with respect to the total of the content of the organic binder and the content of the solvent.

The content of the organic binder in the organic vehicle may be 30% by weight or less, 25% by weight or less, or 20% by weight or less, with respect to the total of the content of the organic binder and the content of the solvent.

The content of the organic vehicle may be 1% by weight or more, 3% by weight or more, 5% by weight or more, or 10% by weight or more, with respect to the resin composition paste. The content of the organic vehicle may be 20% by weight or less, 15% by weight or less, 10% by weight or less, or 5% by weight or less, with respect to the resin composition paste.

### [Other Components]

The resin composition according to the present disclosure may further include other components as necessary in addition to the above-mentioned components, as long as the effects of the resin composition according to the present disclosure are not impaired. The resin composition may include, as the other components, an antifoaming agent, a sensitizer, a surfactant, an antioxidant, a polymerization inhibitor (polymerization inhibitor), a leveling agent, a thickener, a gelling inhibitor, a stabilizer, an antiseptic, a pigment, a rheology modifier, and the like. The other components may be included at 5% by weight or less, 3% by weight or less, or 1% by weight or less with respect to the resin composition.

### <Green Sheet>

A green sheet can be obtained by molding the resin composition according to the present disclosure or the resin composition paste according to the present disclosure into a sheet.

The green sheet according to the present disclosure includes the resin composition according to the present disclosure, thereby reducing a decrease in the viscosity of the glass, and making the glass less likely to be over-sintered, when the green sheet is subjected to sintering together with a conductive layer (in particular, a conductive layer containing Ag).

The green sheet according to the present disclosure can be manufactured in the following manner.

First, the resin composition, a dispersant, a plasticizer, and a solvent are blended in the proportions listed below.
(a) resin composition: 50 parts by weight or more and 200 parts by weight or less (i.e., from 50 parts by weight to 200 parts by weight)
(b) dispersant: 1 part by weight or more and 4 parts by weight or less (i.e., from 1 part by weight to 4 parts by weight)
(d) plasticizer: 0.5 parts by weight or more and 3.0 parts by weight or less (i.e., from 0.5 parts by weight to 3.0 parts by weight)
(e) solvent: 100 parts by weight or more and 300 parts by weight or less (i.e., from 100 parts by weight to 300 parts by weight)

Next, 300 parts by weight or more and 700 parts by weight or less (i.e., from 300 parts by weight to 700 parts by weight) of zirconia balls of 1 mm or more and 5 mm or less (i.e., from 1 mm to 5 mm) in diameter are added to the blended raw materials, and the balls and the materials are mixed and crushed with a ball mill for 3 hours or more and 7 hours or less (i.e., from 3 hours to 7 hours) to obtain a final dispersion slurry for green sheet manufacture. It is to be noted that the resin composition paste according to the present disclosure prepared in advance by blending as mentioned above may be used as it is as a final dispersion slurry.

Next, the final dispersion slurry is supplied onto a substrate such as a carrier sheet and molded into a sheet by a doctor blade method to prepare a green sheet.

The green sheet according to the present disclosure may be appropriately adjusted depending on the use, and may be, for example, 0.1 μm or more and 10 μm or less (i.e., from 0.1 μm to 10 μm).

The green sheet according to the present disclosure can be used for various electronic components. For example, the green sheet according to the present disclosure can be used for an inductor component, a capacitor component, or the like. For example, an inductor, a capacitor, or the like can be fabricated by stacking green sheets with internal electrodes disposed, pressure-bonding the stacked green sheets, and heat-treating for making the pressure-bonded green sheets sintered.

Specifically, electrode disposition sheets are formed by disposing internal electrodes for capacitance formation on the green sheet prepared in the manner described above. Next, a predetermined number of electrode disposition sheets are stacked, and s green sheet (outer layer sheet) without any electrode disposed is stacked on both upper and lower sides of the stacked electrode disposition sheets and subjected to pressure bonding to form a laminate (laminated pressure-bonded body) in which sides of the respective internal electrodes on one end are alternately extended to end surfaces on the different sides.

Then, the laminated pressure-bonded body is subjected to sintering under predetermined conditions, and then, a conductive paste is applied to both ends of the sintered laminate (element), and subjected to baking to form external electrodes electrically connected to the internal electrodes. Thus, a laminated electronic component is obtained. In addition, other laminated electronic components such as a laminated multilayer board can also be manufactured through the step of stacking green sheets.

### <Electronic Component>

The resin composition according to the present disclosure or the resin composition paste according to the present disclosure can be used for electronic components. Examples of such electronic components include an electronic component including an insulating layer including the resin composition according to the present disclosure and a conductive layer. Examples of the electronic components include an inductor component, a capacitor component, and an LC filter component.

Examples of the electronic components include an electronic component manufactured by a stacking method of stacking a plurality of insulating layers with conductor patterns printed and connecting the layers with vias, an electronic component manufactured by a film formation method of applying a conductor pattern through printing on an insulating layer by sputtering, vapor deposition, or the like, and an electronic component manufactured by a photolithography method of repeating insulating layer formation and conductive layer formation in accordance with a process such as photolithography.

A method for manufacturing an inductor component according to an embodiment will be described.

### (Method for Manufacturing Inductor Component)

An insulating paste including quartz as a filler and the resin composition according to the present disclosure is repeatedly applied by screen printing to form an insulating layer. This insulating layer is an insulating layer for an outer layer, located on the outside on one side in the axial direction of a coil.

A photosensitive conductive paste layer is formed by application, and a coil conductor layer and an external electrode conductor layer are then formed by a photolithography process. Specifically, a photosensitive conductive paste containing Ag as a main metal component is applied by screen printing to form a photosensitive conductive paste layer. Furthermore, the photosensitive conductive paste layer is irradiated with ultraviolet rays or the like through a photomask, and developed with an alkaline solution or the like. Thus, a coil conductor layer and an external electrode conductor layer are formed on the insulating layer. In this regard, a desired coil pattern can be drawn in the photomask.

An insulating layer provided with an opening and a via hole is formed by a photolithography process. Specifically, a photosensitive insulating paste is applied by screen printing to be formed on the insulating layer. Furthermore, the photosensitive insulating layer is irradiated with ultraviolet rays or the like through a photomask, and developed with an alkaline solution or the like.

A coil conductor layer and an external electrode conductor layer are formed by a photolithography process. Specifically, a photosensitive conductive paste containing Ag as a main metal component is applied by screen printing to form a photosensitive conductive paste layer. Furthermore, the photosensitive conductive paste layer is irradiated with ultraviolet rays or the like through a photomask, and developed with an alkaline solution or the like. Thus, a conductor layer that connects external electrode conductor layers is formed in the opening, a via hole conductor is formed in the via hole, and a coil conductor layer is formed on the insulating layer and in the opening.

The steps mentioned above are repeated to form a coil conductor layer and an external electrode conductor layer on and in the insulating layer.

The insulating paste is repeatedly applied by screen printing to form an insulating layer. This insulating layer is an insulating layer for an outer layer, located on the outside on the other side in the axial direction of the coil.

Through the foregoing steps, a mother stacked body is obtained.

The mother stacked body is cut into a plurality of unfired stacked bodies with a dicing machine or the like. In the step of cutting the mother stacked body, the external electrode is exposed from the stacked body at the cut surface formed by the cutting.

The unfired stacked body is subjected to firing under predetermined conditions to obtain a laminate. The laminate is subjected to barrel finishing. The part where the external electrode is exposed from the laminate is subjected to Ni plating with a thickness of 2 μm or more and 10 μm or less (i.e., from 2 μm to 10 μm) and Sn plating with a thickness of 2 μm or more and 10 μm or less (i.e., from 2 μm to 10 μm). Through the foregoing steps, an inductor component of 0.4 mm×0.2 mm×0.2 mm is finished.

It is to be noted that the method for forming the conductor pattern is not limited to the method mentioned above, and may be, for example, a printing lamination method with a conductor paste through a screen plate that has an opening formed in a conductor pattern shape, a method of forming a pattern by etching a conductor film formed by a sputtering method, a vapor deposition method, pressure bonding of a foil, or the like, or like a semi-additive method, a method of forming a negative pattern and forming a conductor pattern from a plating film, and then removing an unnecessary part. Furthermore, forming the conductor pattern in multiple stages achieves a high aspect ratio thereby allowing the loss due to resistance at a high frequency to be reduced. More specifically, the method may be a process of repeating the conductor pattern formation mentioned above, a process of repeatedly stacking a wiring formed by a semi-additive process, or a process of forming a part of the stack by a semi-additive process and forming the other by etching a film obtained by plating growth, in combination with a process of further growth, by plating, of the wiring formed by the semi-additive process, for increasing the aspect ratio.

In addition, the conductor material is not limited to the Ag paste as mentioned above, and may be a good conductor such as Ag, Cu, or Au formed by a sputtering method, a vapor deposition method, pressure bonding of a foil, plating, or the like.

In addition, the method for forming the insulating layer, the opening, and the via hole is not limited to the method mentioned above, and may be a method of forming an opening by laser or drilling after pressure bonding of, spin coating with, or spray coating with an insulating material sheet.

In addition, the insulating material is not limited to the glass or ceramic material as mentioned above, and may be an organic material such as an epoxy resin, a fluororesin, or a polymer resin, or may be a composite material such as a glass epoxy resin, but an insulating material that is small in dielectric constant and dielectric loss is preferred.

In addition, the size of the inductor component is not limited to the size mentioned above.

In addition, the method for forming the external electrode is not limited to the method of plating the external conductor exposed by cutting, and may be a method of further forming, after the cutting, an external electrode by dipping with a conductor paste, a sputtering method, or the like, and plating the external electrode.

### (Surface Roughness)

In the electronic component according to the present disclosure, the insulating layer obtained with the use of the resin composition according to the present disclosure is less likely to be over-sintered when the insulating layer is subjected to sintering together with a conductive layer. For example, the interface between the insulating layer and the conductive layer is less likely to be over-sintered, thus making bubbles and the like less likely to be generated, and accordingly, the irregularities of the surface of the insulating layer and/or conductive layer at the interface is more likely to be reduced, and the surface roughness thereof is more likely to be reduced. The reduced surface roughness of the insulating layer and/or conductive layer at the interface makes it easier to maintain the characteristics and reliability as an electronic component. For example, for an inductor component, the resistance loss at a high frequency is reduced, and the Q value is more likely to be improved.

In an embodiment, at the interface between the insulating layer and the conductive layer, the surface roughness Rq of the conductive layer may be 1.0 μm or less, or may be 0.8 μm or less, 0.6 μm or less, or 0.4 μm or less.

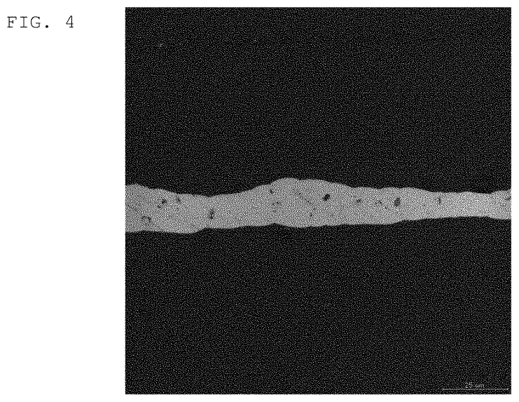

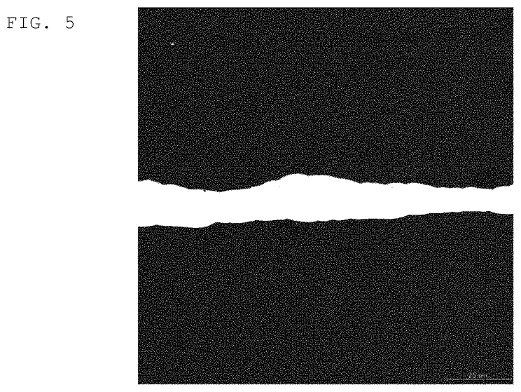

The surface roughness Rq (see JIS B0601:2013 for details) of the conductive layer at the interface between the insulating layer and the conductive layer can be measured in the following manner.
(1) From a DPA section of the electronic component, an internal electrode sectional image (shown in FIG. 4 as a representative view) is acquired. For the image acquisition, the use of a laser microscope, a confocal microscope, an SEM, or the like a suitable image to be acquired.
(2) The obtained image is binarized with the use of image processing software such that the internal electrode part is white, whereas the insulator part is black (shown in FIG. 5 as a representative view). The image processing software is, for example, WinRoof (manufactured by MITANI CORPORATION) or imageJ (manufactured by Wayne Rasband), but is not limited thereto as long as the software is capable of the binarization.
(3) From the binarized image, Rq is calculated for the interface between the internal electrode and the insulator part in accordance with the following formula. Rq represents a root mean square of Z(x) at the reference length l.

$$Rq = \sqrt{\frac{1}{ℓ} {\int }_{0}^{ℓ} {Z}^{2} ( x ) dx} \qquad [ Mathematical Formula 1 ]$$

Although the resin composition according to the present disclosure has been described above, typical examples thereof have been only illustrated. Accordingly, the resin composition according to the present disclosure is not limited thereto, and those skilled in the art will readily understand that various aspects are conceivable.

### EXAMPLES

Examples of the present disclosure will be described below, but the examples is not intended to limit the following disclosure.

### Examples and Comparative Example

As glass compositions, Examples 1 to 5 and Comparative Example 1 with compositions of SiO₂, B₂O₃, and K₂O as shown in Table 5 were prepared. The compositions shown in Table 5 were confirmed by XRF.

Example 1 (Ag added) to Example 5 (Ag added) and Comparative Example 1 (Ag added) were prepared by adding 7% by weight of silver to Example 1 to 5 and Comparative Example 1.

### <Testing Method>

The test procedures are as follows.

[High Temperature Rheology Measurement] For measuring the complex viscosities of the examples, comparative example, examples (Ag added), and comparative example (Ag added) with a high-temperature rheometer, green compacts were prepared from the glass frits shown by the examples and comparative examples under the conditions in Table 3 below.

TABLE 3

| Apparatus/Part | Pressing Machine | 20 t pressing machine |
|---|---|---|
| Material | Mold | φ = 1 cm circle |
| Processing | Load [t] | 10 |
| Conditions | Filling Depth [mm] | 5 |
| | Load Holding Time [sec] | 5 |

The prepared green compact was set in a high-temperature rheometer, and the complex viscosity was measured under the conditions in Table 4 below. The results of measuring the complex viscosity are shown in Table 5.

TABLE 4

| | High | |
|---|---|---|
| Apparatus/Part | Temperature | MCR302 (manufactured |
| Material | Rheometer | by Anton Paar) |
| Measurement | Measurement | 550 to 950° C. |
| Conditions | Temperature | (step temperature rise |
| | | at 25° C./6 min) |
| | Measurement | any value of 0.1 to 10 Hz |
| | Frequency | |
| | Normal Force | 10N |

### [Rate of Decrease in Complex Viscosity by Addition of 7% by Weight of Ag]

The rate of decrease in complex viscosity by the addition of 7% by weight of Ag was calculated from the following formula.

“rate of decrease in complex viscosity of glass frit with Ag added=100−complex viscosity of glass frit with Ag added/complex viscosity of glass frit alone×100”

The examples and comparative example were determined as follows from the rate of decrease in complex viscosity by addition of 7% by weight of Ag.

Of the rates of decreases at 901° C. and 926° C., the larger rate of decrease is:
less than 30%; ⊙ (best)
30% or more and less than 40% (i.e., from 30% to less than 40%); ◯ (good)
40% or more and less than 80% (i.e., from 40% to less than 80%); Δ (acceptable) (no problem in practical use);
80% or more; × (not acceptable) (problem in practical use).

### [Softening Point]

The softening points of the examples, comparative example, examples (Ag added), and comparative example (Ag added) were measured by DTA in accordance with the following conditions. The results of measuring the softening points are shown in Table 5.

Thirty mg of the glass frit with a median diameter (D50) of 0.1 μm or more and 5.0 μm or less (i.e., from 0.1 μm to 5.0 μm) was used, and a platinum pan was used as a container for the glass frit. The skirt (fourth inflection point) of the second endothermic peak as viewed from the low-temperature side of a DTA chart obtained by temperature increase from room temperature to 950° C. at 10° C./min under the air atmosphere with the use of α-alumina as a reference was defined as a glass softening point.

### [SEM Observation]

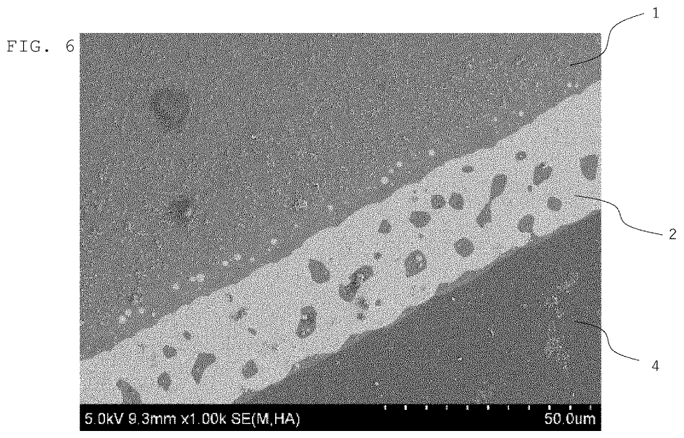

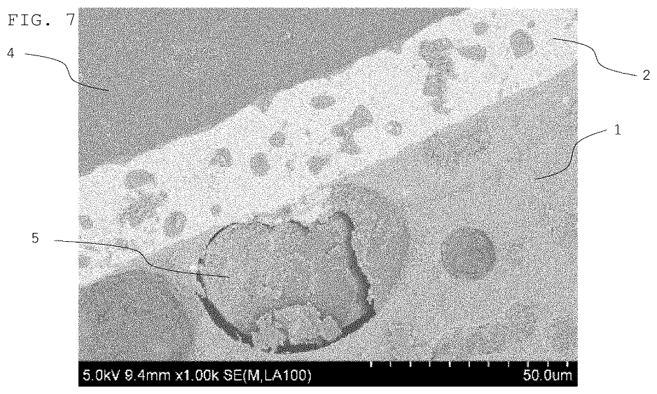

The glass frits with the compositions listed in Example 1 and Comparative Example 2 were each subjected to sintering together with an Ag-containing electrode to prepare Ag-GL co-sintered bodies (see FIG. 5). Ag-GL interfaces of sections obtained by embedding the co-sintered bodies in a resin and polishing the embedded bodies were observed with an SEM. The SEM images are shown in FIGS. 6 and 7.

TABLE 5

| | DTA | Glass Composition (XRF) [wt. %] | | | | |
|---|---|---|---|---|---|---|
| Glass | Softening | | | | B₂O₃/(SiO₂ | K₂O/(SiO₂ |
| Product | Point [° C.] | SiO₂ | B₂O₃ | K₂O | [symbol] | [symbol] |
| Example 1 | 785 | 82.0 | 15.0 | 3.0 | 0.15 | 0.031 |
| Example 2 | 806 | 83.5 | 15.0 | 1.5 | 0.15 | 0.015 |
| Example 3 | 800 | 83.5 | 15.5 | 1.0 | 0.16 | 0.010 |
| Example 4 | 803 | 83.5 | 13.5 | 3.0 | 0.14 | 0.031 |
| Example 5 | 807 | 84.0 | 13.0 | 3.0 | 0.13 | 0.031 |
| Comparative | 861 | 70.0 | 25.0 | 5.0 | 0.26 | 0.053 |
| Example 1 | | | | | | |

| | | | | | | | | Rate of | | |
|---|---|---|---|---|---|---|---|---|---|---|
| | | | | | | | | Decrease | | |
| | Result of High Temperature Rheology Measurement | | | | | | | in Complex | | |
| | (complex viscosity @1.1 Hz [mPa · s]) | | | | | | | Viscosity | | |
| Glass | Presence | | | | | | | [symbol] | | |
| Product | or Absenc [symbol] | 726° C. | 776° C. | 826° C. | 876° C. | 901° C. | 926° C. | 901° C. | 926° C. | Determination |
| Example 1 | GL | 8.1 × 10 | 3.3 × 10 | 1.1 × 10 | 3.7 × 10 | 2.1 × 10 | 1.2 × 1 | 39% | 37% | ◯ |
| | Ag | 6.7 × 10 | 3.0 × 10 | 7.5 × 10 | 2.3 × 10 | 1.3 × 10 | 7.6 × 1 | | | |
| Example 2 | GL | 9.5 × 10 | 6.0 × 10 | 3.3 × 10 | 1.1 × 10 | 8.0 × 10 | 5.8 × 1 | 44% | 54% | Δ |
| | Ag | 7.9 × 10 | 5.2 × 10 | 2.6 × 10 | 7.5 × 10 | 4.5 × 10 | 2.6 × 1 | | | |
| Example 3 | GL | 1.1 × 10 | 7.4 × 10 | 4.1 × 10 | 1.6 × 10 | 1.2 × 10 | 9.5 × 1 | 38% | 50% | Δ |
| | Ag | 9.4 × 10 | 6.3 × 10 | 3.0 × 10 | 1.1 × 10 | 7.3 × 10 | 4.8 × 1 | | | |
| Example 4 | GL | 7.9 × 10 | 4.6 × 10 | 1.3 × 10 | 4.2 × 10 | 2.3 × 10 | 1.2 × 1 | 29% | 24% | ⊚ |
| | Ag | 6.1 × 10 | 3.1 × 10 | 9.4 × 10 | 3.2 × 10 | 1.7 × 10 | 9.4 × 1 | | | |
| Example 5 | GL | 9.5 × 10 | 6.4 × 10 | 2.3 × 10 | 6.5 × 10 | 3.6 × 10 | 1.9 × 1 | 20% | 17% | ⊚ |
| | Ag | 7.6 × 10 | 4.8 × 10 | 1.9 × 10 | 5.2 × 10 | 2.8 × 10 | 1.6 × 1 | | | |
| Comparative | GL | 4.9 × 10 | 5.4 × 10 | 4.9 × 10 | 2.5 × 10 | 1.3 × 10 | 6.8 × 1 | 83% | 85% | X |
| | Ag | 5.5 × 10 | 4.6 × 10 | 2.1 × 10 | 4.8 × 10 | 2.2 × 10 | 1.0 × 1 | | | |

Ag added: GL alone with 7% by weight of Ag added thereto [symbol]
indicates data missing or illegible when filed

From Table 5, the rates of decreases in complex viscosity by addition of 7 wt % of Ag in Examples 1 to 5 have been found to be lower than that in Comparative Example 1.

Aspects of the resin composition and manufacturing method therefor according to the present disclosure are as follows.

<Item 1> A resin composition including: a glass frit; an inorganic filler; an alkali-soluble resin; a photosensitive monomer; and a photopolymerization initiator, where the rate of decrease in the complex viscosity of the glass frit with 7% by weight or less of Ag added to the glass frit is less than 40% at 900° C. and less than 60% at 926° C., as compared with a case without Ag added.

<Item 2> The resin composition according to item 1, where the rate of decrease in complex viscosity with 7% by weight of Ag added is less than 30% at 900° C. and less than 30% at 926° C. as compared with a case without Ag added.

<Item 3> The resin composition according to item 1 or 2, where the glass frit has an average particle size of 0.1 μm or more and 5.0 μm or less (i.e., from 0.1 μm to 5.0 μm).

<Item 4> The resin composition according to any one of items 1 to 3, where the glass frit includes SiO₂, X₂O₃(X is Al or B), and R₂O (R is an alkali metal element).

<Item 5> The resin composition according to item 4, where the ratio of the amount of X₂O₃ to the total amount of SiO₂ and X₂O₃ meets X₂O₃/(SiO₂+X₂O₃)<0.200.

<Item 6> The resin composition according to item 4, where the ratio of the amount of R₂O to the total amount of SiO₂ and X₂O₃ meets 0.008<R₂O/(SiO₂+X₂O₃)<0.042.

<Item 7> The resin composition according to any one of items 1 to 6, where the inorganic filler includes at least one or more selected from the group consisting of Mg₂SiO₄, CaSiO₃, ZrO₂, Al₂O₃, CeO, TiO₂, Fe₂O₃, SiO₂, CoAl₂O₄, and perovskite-type oxides represented by a general formula: ABO₃ [the constituent element at the A site in the formula includes at least one selected from the group consisting of Ag, K, La, Sr, Ca, and Ba, and the constituent element at the B site in the formula includes at least one selected from the group consisting of Nb, Ca, Co, Ti, Zr, and Fe].

<Item 8> A resin composition paste including: the resin composition according to any one of items 1 to 7; a solvent; and a dispersant and/or a plasticizer.

<Item 9> The resin composition paste according to item 8, where the dispersant is an anionic dispersant.

<Item 10> A green sheet obtained by molding the resin composition according to any one of items 1 to 7 into a sheet.

<Item 11> An electronic component including: an insulating layer including the resin composition according to any one of items 1 to 7; and a conductive layer including Ag.

<Item 12> The electronic component according to item 11, where the conductive layer has a surface roughness Rq of 1.0 μm or less at the interface between the insulating layer and the conductive layer.

<Item 13> A method for manufacturing an electronic component, including forming a laminate by laminating an insulating layer including the resin composition according to any one of items 1 to 7 and a conductive layer including Ag; and heat-treating the laminate.

<Item 14> The manufacturing method according to item 13, where the conductive layer is laminated on the insulating layer by photolithography.

What is claimed is:

1. A resin composition comprising:
a glass frit;
an inorganic filler;
an alkali-soluble resin;
a photosensitive monomer; and
a photopolymerization initiator,
wherein a rate of decrease in complex viscosity of the glass frit with 7% by weight or less of Ag added to the glass frit is less than 40% at 900° C. and less than 60% at 926° C., as compared with a case without Ag added.

2. The resin composition according to claim 1, wherein
the rate of decrease in complex viscosity with 7% by weight of Ag added is less than 30% at 900° C. and less than 30% at 926° C. as compared with a case without Ag added.

3. The resin composition according to claim 1, wherein
the glass frit has an average particle size of from 0.1 μm to 5.0 μm.

4. The resin composition according to claim 1, wherein
the glass frit includes SiO₂, X₂O₃(X is Al or B), and R₂O (R is an alkali metal element).

5. The resin composition according to claim 4, wherein
a ratio of an amount of X₂O₃ to a total amount of SiO₂ and X₂O₃ meets X₂O₃/(SiO₂+X₂O₃)<0.200.

6. The resin composition according to claim 4, wherein
a ratio of an amount of R₂O to a total amount of SiO₂ and X₂O₃ meets 0.008<R₂O/(SiO₂+X₂O₃)<0.042.

7. The resin composition according to claim 1, wherein
the inorganic filler includes at least one or more selected from the group consisting of Mg₂SiO₄, CaSiO₃, ZrO₂, Al₂O₃, CeO, TiO₂, Fe₂O₃, SiO₂, CoAl₂O₄, and perovskite-type oxides represented by a general formula: ABO₃
[a constituent element at an A site in the formula includes at least one selected from the group consisting of Ag, K, La, Sr, Ca, and Ba, and a constituent element at a B site in the formula includes at least one selected from the group consisting of Nb, Ca, Co, Ti, Zr, and Fe].

8. A resin composition paste comprising:
the resin composition according to claim 1;
a solvent; and
at least one of a dispersant or a plasticizer.

9. The resin composition paste according to claim 8, wherein
the dispersant is an anionic dispersant.

10. A green sheet obtained by molding the resin composition according to claim 1 into a sheet.

11. An electronic component comprising:
an insulating layer including the resin composition according to claim 1; and
a conductive layer including Ag.

12. The electronic component according to claim 11, wherein
the conductive layer has a surface roughness Rq of 1.0 μm or less at an interface between the insulating layer and the conductive layer.

13. A method for manufacturing an electronic component, comprising:
forming a laminate by laminating an insulating layer including the resin composition according to claim 1 and a conductive layer including Ag; and
heat-treating the laminate.

14. The manufacturing method according to claim 13, wherein
the conductive layer is laminated on the insulating layer by photolithography.
